(19) United States
(12) Patent Application Publication
(10) Pub. No.: US 2026/0136552 A1
(43) Pub. Date: May 14, 2026

(54) DOUBLE POLY NON-VOLATILE MEMORY BIT CELL

(71) Applicant: SEMICONDUCTOR COMPONENTS INDUSTRIES, LLC, Scottsdale, AZ (US)

(72) Inventors: Gang LIU, Camas, WA (US); Santosh MENON, Portland, OR (US); Adam Peter COSMIN, San Jose, CA (US); Bruce Blair GREENWOOD, Gresham, OR (US)

(73) Assignee: SEMICONDUCTOR COMPONENTS INDUSTRIES, LLC, Scottsdale, AZ (US)

(21) Appl. No.: 18/943,224

(22) Filed: Nov. 11, 2024

(51) Int. Cl. H10B 41/35; H01L 21/28; H01L 29/423; H01L 29/66; H01L 29/788; H10B 41/10

(52) U.S. Cl. CPC H10B 41/35; H10B 41/10; H10D 30/0411; H10D 30/683; H10D 30/6892; H10D 64/035

(57) ABSTRACT

A non-volatile memory (NVM) bit cell is disclosed. The NVM bit cell includes a control gate, a state transistor, and an access transistor coupled in series with the state transistor. The control gate includes a floating terminal formed by a first polysilicon layer, a control terminal formed by a second polysilicon layer, and a control-gate dielectric layer formed between the first polysilicon layer and the second polysilicon layer, wherein the control-gate dielectric layer includes a high-K dielectric layer. The state transistor comprises a floating-gate terminal formed by the first polysilicon layer and coupled to the floating terminal of the control gate. The state transistor further comprises a tunnel oxide layer formed between the first polysilicon layer and an active area of the state transistor.

### TECHNICAL FIELD

The disclosure relates generally to integrated circuit technology, and particularly to a design and method of manufacturing a non-volatile memory device.

### BACKGROUND

Integrated circuits may be fabricated to include both a data processing unit, such as a central processing unit or a graphics processing unit, as well as a memory block that may be used to store data for use by the data processing unit. In some configurations, the memory block may include a non-volatile memory (NVM) such as an electrically erasable programmable read only memory (EEPROM).

Conventional technologies for including non-volatile memory on the same complementary metal-oxide semiconductor (CMOS) integrated circuit as a data processing unit have leveraged the gate oxide of the CMOS process to instantiate a logic-based, single-poly, floating gate EEPROM. The inventors of embodiments of the present disclosure have recognized that such embedded single-poly EEPROM cells typically require control gate and floating gate transistors separate from an access transistor and a state transistor, as well as isolation thereof. Relatedly, the inventors of embodiments of the present disclosure have also recognized that the footprint of such embedded single-poly EEPROM cells is typically large, thus consuming significant area of the semiconductor die. Other NVM technologies using multiple poly layers have been designed with a smaller footprint than single-poly EEPROM cells. But the inventors of embodiments of the present disclosure have recognized that such other NVM technologies have suffered from higher process cost and lower reliability. Embodiments of the present disclosure may address one or more of these challenges.

### BRIEF DESCRIPTION OF THE DRAWINGS

A more complete understanding of the present embodiments may be acquired by referring to the following description taken in conjunction with the accompanying drawings, in which like reference numbers indicate like features.

FIG. 1 illustrates a block diagram of an integrated circuit in accordance with embodiments of the present disclosure.

FIG. 2 illustrates a schematic diagram of a non-volatile memory bit cell in accordance with embodiments of the present disclosure.

FIG. 3 is a chart illustrating operating conditions of a non-volatile memory bit cell in accordance with embodiments of the present disclosure.

FIG. 4 illustrates a top view of semiconductor process areas for a non-volatile memory bit-cell array in accordance with embodiments of the present disclosure.

FIG. 5A illustrates a cross-section view of an array of non-volatile memory bit cells in accordance with embodiments of the present disclosure.

FIG. 5B illustrates a cross-section view of an array of non-volatile memory bit cells in accordance with embodiments of the present disclosure.

FIG. 5C illustrates a cross-section view of an array of non-volatile memory bit cells in accordance with embodiments of the present disclosure.

FIG. 6 is a chart illustrating operating conditions of a non-volatile memory bit cell in accordance with embodiments of the present disclosure.

FIG. 7 illustrates a method for manufacturing an non-volatile memory bit cell in accordance with embodiments of the present disclosure.

### DETAILED DESCRIPTION

Details of one or more embodiments are set forth in the description below and the accompanying drawings. Other features will be apparent from the description, drawings, and from the claims.

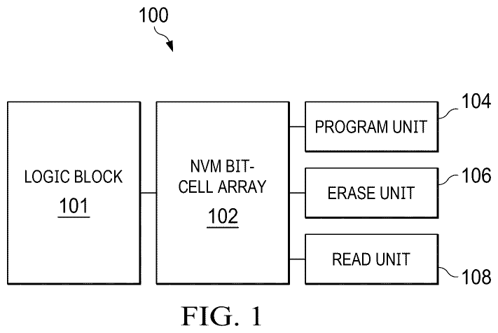

FIG. 1 illustrates a block diagram of integrated circuit 100 in accordance with embodiments of the present disclosure. Integrated circuit 100 may include logic block 101, non-volatile memory (NVM) bit-cell array 102, program unit 104, erase unit 106, and read unit 108. Logic block 101 may include a data processing unit, such as a central processing unit or a graphics processing unit. NVM bit-cell array 102 may comprise a plurality of NVM bit cells arranged in multiple rows and in multiple columns. Logic block 101 may be coupled to NVM bit-cell array 102 and may utilize NVM bit-cell array 102 to store information that may be used in one or more data processing functions.

Program unit 104, erase unit 106, and read unit 108 may be configured to provide the respective voltages to NVM bit-cell array 102 for programming, erasing, and reading bit cells within NVM bit-cell array 102. As shown in FIG. 1, program unit 104, erase unit 106, and read unit 108 may in some embodiments be implemented as separate units. In other embodiments, program unit 104, erase unit 106, and read unit 108 may be implemented together in a single circuit with, for example, a charge pump and one or more voltage dividers that may collectively be used to generate the different respective voltages used for programming, erasing, and reading one or more bit cells of NVM bit-cell array 102.

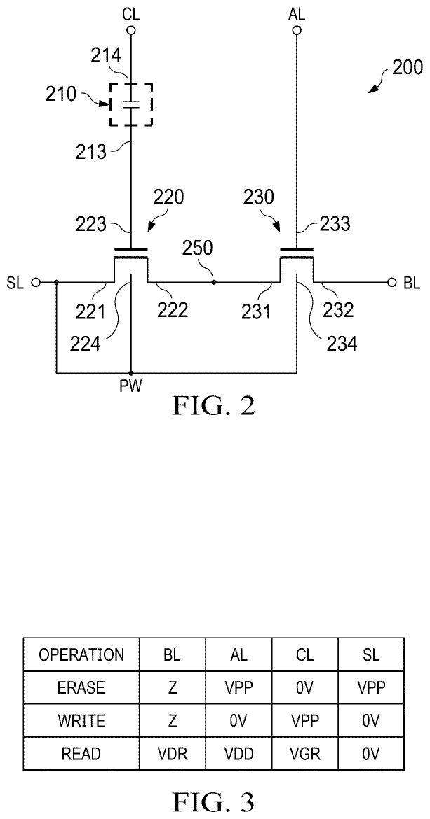

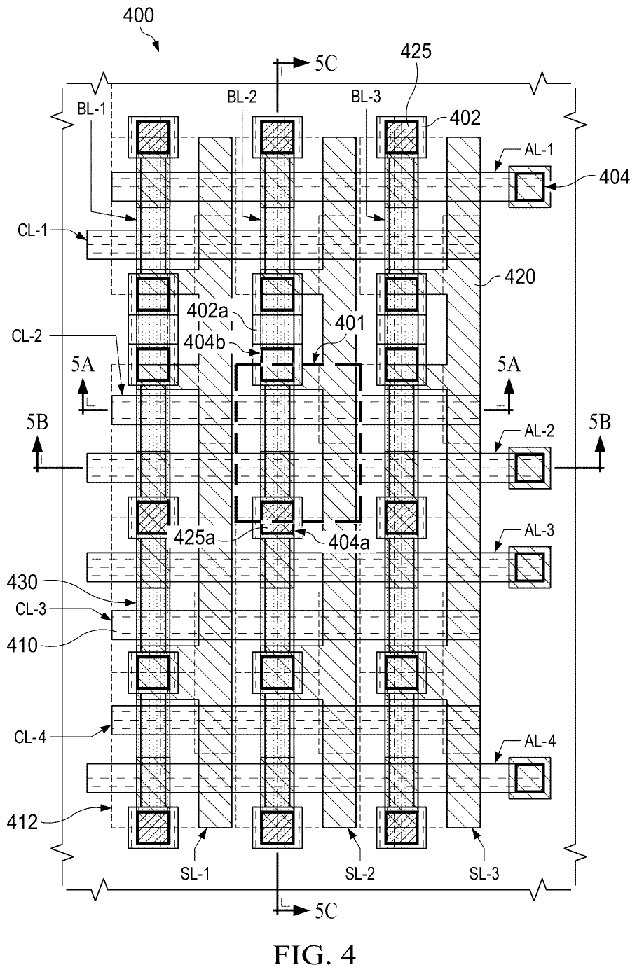

FIG. 2 illustrates a schematic diagram of non-volatile memory (NVM) bit cell 200 in accordance with embodiments of the present disclosure. NVM bit cell 200 may include control gate 210, state transistor 220, and access transistor 230. NVM bit cell 200 may also be connected to various input and output lines used to program, erase, and read the status of NVM bit cell 200. For example, as described in further detail below, various terminals of NVM bit cell 200 may be coupled to the access line AL, the control line CL, the source line SL, the bit line BL, and the p-well line PW. As also described below with reference to FIGS. 4-6, NVM bit cell 200 may represent one bit cell in an array of bit cells with multiple rows and multiple columns formed of different instances of NVM bit cell 200. Thus, as described in further detail below, one instance of NVM bit cell 200 may share connections to one or more of the access line AL, the control line CL, the source line SL, the bit line BL, and the p-well line PW with other instances of NVM bit cell 200.

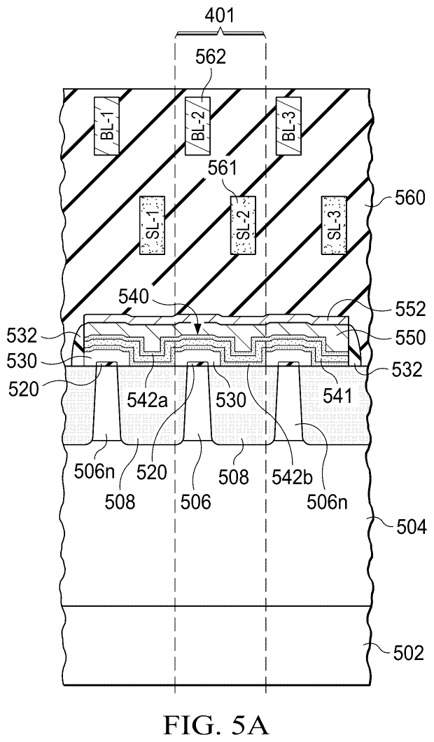

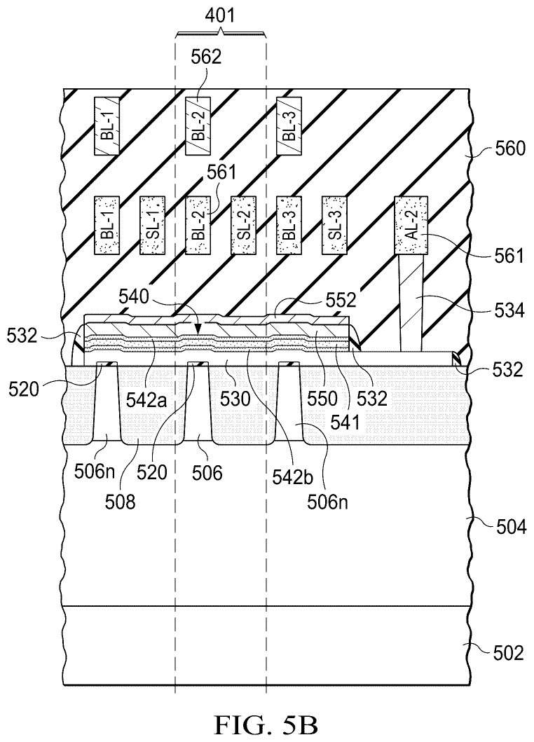

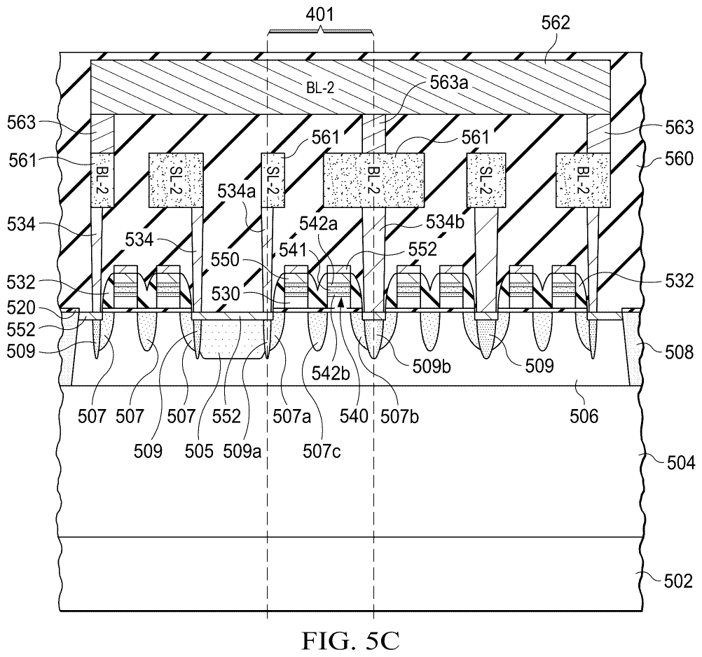

Control gate 210 may include floating terminal 213 and control terminal 214. Control terminal 214 may be coupled to the control line CL. Floating terminal 213 may be coupled to floating-gate terminal 223 of state transistor 220. As described in further detail below with reference to FIG. 5A, control gate 210 may include a capacitance from a first polysilicon layer that forms floating terminal 213, across a control-gate dielectric layer, and to a second polysilicon layer that forms control terminal 214. For the purposes of the present disclosure, a “polysilicon layer” or a “layer of polysilicon” may also be referred to as a “poly layer” or a “layer of poly.” The first polysilicon layer may be a shared polysilicon layer that may form both floating terminal 213 of control gate 210 and floating-gate terminal 223 of state transistor 220. Accordingly, the floating terminal 213 of control gate 210 may be coupled to the floating-gate terminal 223 of state transistor 220 by virtue of both terminals be formed by the shared first polysilicon layer.

As described in further detail below with reference to FIG. 5A, the control-gate dielectric layer may include a high-K dielectric layer. The high-K dielectric layer may have a higher dielectric constant than, for example, silicon dioxide. The high-K dielectric layer may thus increase the capacitance across control gate 210 and improve the capacitive coupling between control terminal 214 and floating terminal 213. The improved capacitive coupling between control terminal 214 and floating terminal 213 may thus reduce the voltage necessary to induce Fowler-Nordheim tunneling across control gate 210 during write and erase operations, such as those operations described below with reference to FIG. 3. The reduced voltage may in turn reduce the stress incurred by control gate 210 and state transistor 220 during write and erase operations, thereby improving reliability of NVM bit cell 200. In addition, reducing the voltage required to induce the Fowler-Nordheim tunneling may provide the further advantage of reducing the size and complexity of the supply circuitry, such as a charge pump and/or high-voltage logic circuitry, required to generate the necessary voltage levels.

State transistor 220 may include source terminal 221 coupled to the source line SL and drain terminal 222 coupled to intermediate node 250. State transistor 220 may also include floating-gate terminal 223 coupled to floating terminal 213 of control gate 210. The gate of state transistor 220 may be implemented with a state-transistor tunnel oxide layer located under the shared polysilicon layer that forms both floating terminal 213 of control gate 210 and floating-gate terminal 223 of state transistor 220. As described in further detail below, state transistor 220 may be formed in a well region, for example, a p-well region. In embodiments where the well region is a p-well region, state transistor 220 may be an n-type metal-oxide semiconductor field effect transistor (“N-type MOSFET” or “NMOS transistor”) and may thus be referred to as a NMOS state transistor. Further, in such embodiments, state transistor 220 may include body terminal 224 coupled to the p-well line PW.

Access transistor 230 may be coupled in series with state transistor 220. For example, access transistor 230 may include source terminal 231 coupled to drain terminal 222 of state transistor 220 at intermediate node 250. Access transistor 230 may also include drain terminal 232 coupled to the bit line BL and gate terminal 233 coupled to the access line AL. Similar to state transistor 220, the gate of access transistor 230 may be implemented with a tunnel oxide layer located under a polysilicon layer forming gate terminal 233. As described in further detail below, access transistor 230 may be formed in a well region, for example, a p-well region, along with state transistor 220. In embodiments where the well region is a p-well region, access transistor 230 may be an NMOS transistor, and may thus be referred to as an NMOS access transistor. Further, in such embodiments, access transistor 230 may include body terminal 234 coupled to the p-well line PW.

FIG. 3 is a chart illustrating the operating conditions of NVM bit cell 200 in accordance with embodiments of the present disclosure. As shown in FIG. 2, the p-well line PW for NVM bit cell 200 may be coupled to the source line SL. Thus, the p-well line PW is not separately included in the chart of FIG. 3. As described directly below, state transistor 220 and control gate 210 may be collectively configured to utilize Fowler-Nordheim tunneling for an erase operation and for a write operation.

To perform an erase operation, the bit line BL may be set to high impedance, as represented by “Z” in FIG. 3. For example, any other external connections to the bit line BL may be turned off such that there is an open-circuit high-impedance condition on the bit line BL. A program voltage VPP may be applied to the access line AL and the source line SL. As described above with reference to FIG. 2, the p-well line PW may be coupled to the source line SL. Thus, by applying a VPP of, for example, 10 volts to the source line SL, that same program voltage VPP may be applied to the p-well line PW. Further, a nominal voltage, of for example, 0 volts may be applied to the control line CL. The program voltage VPP may be, for example, 10 volts, or any other voltage higher than the voltage applied to the control line CL suitable to induce Fowler-Nordheim tunneling as described directly below.

With a VPP of 10 volts, for example, applied to the p-well line PW, and a nominal voltage of 0 volts applied to the control line CL, the large voltage drop may cause electron tunneling across the state-transistor tunnel oxide layer of state transistor 220 and the control-gate dielectric layer of control gate 210. As described below with reference to FIGS. 5A-5C, a first gate capacitance across the control-gate dielectric layer of control gate 210 may be larger than a second gate capacitance across the state-transistor tunnel oxide layer of state transistor 220. Accordingly, the first gate capacitance of control gate 210 may have a larger influence than the second gate capacitance of state transistor 220 on the amount of charge stored on the shared polysilicon layer that forms floating terminal 213 of control gate 210 and floating-gate terminal 223 of state transistor 220 during an erase operation. The first gate capacitance of control gate 210 may thus also have a larger influence than the second gate capacitance of state transistor 220 on the resulting voltage at floating terminal 213 of control gate 210 and floating-gate terminal 223 of state transistor 220 due an erase operation. For example, in embodiments where control gate 210 has a first gate capacitance four times larger than a second gate capacitance of state transistor 220, applying a VPP of 10 volts to the source line SL (and thus to the p-well line PW) and a nominal voltage of 0 volts to the control line CL, may provide a charge accumulation at the shared polysilicon layer forming floating terminal 213 and floating-gate terminal 223, resulting in an erase-state voltage of approximately 2 volts. When the erase-operation voltages are removed from the p-well line PW and the control line CL, the charge accumulated at the shared polysilicon layer forming floating terminal 213 and floating-gate terminal 223 may remain and may thus be used for detecting the erase-state during a subsequent read operation.

As described above, the program voltage VPP may also be applied to the access line AL during the erase operation. Applying VPP to the access line AL during the erase operation, when VPP is also applied to the source line SL and the p-well line PW, may prevent unwanted stress from being applied across the gate of the access transistor 230 during the erase operation.

To perform an write operation, the bit line BL may be set to high impedance, as represented by “Z” in FIG. 3. For example, any other external connections to the bit line BL may be turned off such that there is an open-circuit high-impedance condition on the bit line BL. A nominal voltage, of for example 0V, may be applied to the access line AL and the source line SL. As described above with reference to FIG. 2, the p-well line PW may be coupled to the source line SL. Thus, by applying a nominal voltage of, for example, 0V to the source line SL, the same nominal voltage may be applied to the p-well line PW. Further, a program voltage VPP may be applied to the control line CL. The program voltage VPP may be, for example, 10 volts, or any other voltage higher than the voltage applied to the p-well line PW suitable to induce Fowler-Nordheim tunneling as described directly below.

With, for example, a VPP of 10 volts applied to the control line CL, and a nominal voltage of 0 volts applied to the p-well line PW, the large voltage drop may cause electron tunneling across the control-gate dielectric layer of control gate 210 and the state-transistor tunnel oxide layer of state transistor 220. As described below with reference to FIGS. 5A-5C, the first gate capacitance across the control-gate dielectric layer of control gate 210 may be larger than the second gate capacitance across the state-transistor tunnel oxide layer of state transistor 220. Accordingly, the first gate capacitance of control gate 210 may have a larger influence than the second gate capacitance of state transistor 220 on the amount of charge stored on the shared polysilicon layer that forms floating terminal 213 of control gate 210 and floating-gate terminal 223 of state transistor 220 during a write operation. The first gate capacitance of control gate 210 may thus also have a larger influence than the second gate capacitance of state transistor 220 on the resulting voltage at floating terminal 213 of control gate 210 and floating-gate terminal 223 of state transistor 220 due to a write operation. For example, in embodiments where control gate 210 has a first gate capacitance four times larger than a second gate capacitance of state transistor 220, applying a VPP of 10 volts to the control line CL and a nominal voltage of 0 volts to the p-well line PW, may provide a charge accumulation at the shared polysilicon layer, which forms floating terminal 213 of control gate 210 and floating-gate terminal 223 of state transistor 220, resulting in a write-state voltage of approximately 8 volts. When the write-operation voltages are removed from the p-well line PW and the control line CL, the charge accumulated at the shared polysilicon layer forming floating terminal 213 and floating-gate terminal 223 may remain and may thus be used for detecting the write-state during a subsequent read operation.

As described above, the nominal voltage of, for example 0V, may also be applied to the access line AL during the write operation. Applying the nominal voltage to the access line AL during the erase operation, when nominal voltage is also applied to the source line SL and the p-well line PW, may prevent unwanted stress from being applied across the gate of the access transistor 230 during the write operation.

After an erase operation or a write operation, a read operation may be performed by turning on access transistor 230, applying a drain-to-source voltage across state transistor 220, and monitoring the current conducted by state transistor 220. The current conducted by state transistor 220 for a given drain-to-source source voltage may depend on the charge accumulation remaining at the shared polysilicon layer forming floating terminal 213 and floating-gate terminal 223 and may thus indicate whether NVM bit cell 200 is in an erase-state or a write-state.

For example, during a read operation, a nominal voltage of zero volts may be applied to the source line SL. A supply voltage VDD may be applied to the access line AL. In some embodiments, the VDD voltage may be for example 1.8 volts, or any other voltage suitable to turn on access transistor 230 and to drive access transistor 230 in saturation. Further, a gate-read voltage VGR may be applied to the control line. The gate-read voltage VGR, may, in combination with the charge accumulated on the shared polysilicon layer forming floating terminal 213 and floating-gate terminal 223, provide a bias voltage to floating-gate terminal 223 of state transistor 220. For example, the gate-read voltage VGR may be placed at any suitable baseline voltage such that state transistor 220 may be biased in an on-state if the NVM bit cell 200 was placed in a write-state before the read operation, and may be biased in an off-state if the NVM bit cell 200 was placed in an erase-state before the read operation. Further, a drive voltage (VDR) may be applied to bit line BL. The drive voltage VDR may be utilized to apply a drain-to-source voltage across state transistor 220. In some embodiments, VDR may be equal to the VDD voltage of 1.8V for example. With the VDR voltage applied to the bit line BL, a nominal voltage of for example 0 volts applied to the source line SL, and access transistor 230 driven in an on-state, the amount of current conducted at the bit line BL may depend on the biasing at the floating-gate terminal 223 of state transistor 220. Thus, the amount of current conducted at the bit line BL may indicate whether NVM bit cell 200 was last placed in an erase-state or a write-state prior to the read operation.

Although the example voltage values for the read operation shown in FIG. 3 lists a nominal voltage of 0V for the source line SL and p-well line and positive voltages for bit line BL and access line AL, alternative voltage values with the same relative difference may be utilized to achieve the same read operation. For example, the bit line BL and access line AL may be placed at a nominal voltage of zero volts while the source line SL and p-well line PW are placed at a negative voltage of, for example, −1.8 volts. In such embodiments, the gate-read voltage VGR may be similarly adjusted such that state transistor 220 may be biased in an on-state if the NVM bit cell 200 was placed in a write-state before the read operation, and may be biased in an off-state if the NVM bit cell 200 was placed in an erase-state before the read operation.

Further, although the above embodiments refer to tunnelling during the erase operation and the write operation such that state transistor 220 may be placed in an on-state during a read operation following a write operation, and may be placed in an off-state during a read operation following an erase operation, the designation of “WRITE” and “ERASE” may be switched. For example, in alternate embodiments, the designation of the “ERASE” and “WRITE” operations in FIG. 3 may be switched with each other such that state transistor 220 may be placed in an on-state during a read operation following an erase operation and may be placed in an off-state during a read operation following a write operation.

FIG. 4 illustrates a top view of semiconductor process areas for a non-volatile memory (NVM) bit-cell array in accordance with embodiments of the present disclosure. Certain semiconductor process areas are described with reference to the top view of FIG. 4 and may be utilized to manufacture the elements of an NVM bit cell 401. NVM bit cell 401 may represent an embodiment of NVM bit cell 200 described above with reference to FIG. 2, including control gate 210, state transistor 220, and access transistor 230. As shown in FIG. 4, a single instance of NVM bit cell 401 may be repeated in an array. Rows of the array may be formed by instances of similarly oriented NVM bit cells repeated side to side, and columns of the array may be formed by instances of NVM bit cells oriented in a mirrored fashion up and down.

As shown in FIG. 4, the semiconductor process areas may include active areas 402, contact areas 404, polysilicon areas 410, exclude areas 412, first metal layer areas 420, via areas 425, and second metal layer areas 430.

Active areas 402 may be utilized to form the wells in which the access transistor and the state transistor of each NVM bit cell may be formed. Active areas 402 may also be utilized to form a silicide on the active areas of each bit cell, which may improve the electrical conductivity of contacts to underlying regions. Further, active areas 402 may be utilized to delineate areas of trench isolation. For example, in some embodiments, any area outside of active areas 402 may include a trench region.

Contact areas 404 may be utilized to form contacts from underlying active or polysilicon areas to above metal layers. For example, contact area 404a may be utilized, in conjunction with a first metal layer area 420 and a via area 425a, to couple a drain terminal of the access transistor of NVM bit cell 401 to a second metal layer area 430 forming the bit line (BL-2) for the column in which NVM bit cell is located. As another example, contact area 404b may be utilized to couple a source terminal of the state transistor of NVM bit cell 401 to a first metal layer area 420 forming the source line (SL-2) for the column in which NVM bit cell 401 is located.

Polysilicon areas 410 may be utilized to pattern a first layer of polysilicon and a second layer of polysilicon. As described in further detail below with reference to FIGS. 5A-5C, the first polysilicon layer may be utilized to form the floating-gate terminal of the state transistor of NVM bit cell 401. Further, the first and second layers of polysilicon may be utilized to respectively form the floating terminal and the control terminal of the control gate of NVM bit cell 401. Exclude areas 412 may also be utilized to pattern the first polysilicon layer. Specifically, the first layer of polysilicon may be omitted from areas outside of exclude areas 412.

First metal layer areas 420 may be utilized to pattern areas of a first layer of metal that may be used for coupling NVM bit cell 401 to various lines. Second metal layer areas 430 may similarly be used to pattern areas of a second layer of metal that may be located above the first layer of metal and likewise may be used for coupling NVM bit cell 401 to various lines. Via areas 425 may be used to form vias between different patterned areas of the first layer of metal and the second layer of metal.

As shown in FIG. 4, a single instance of NVM bit cell 401 may be repeated in an array with multiple rows and multiple columns. Instances of the NVM bit cell in the same row or column may share various lines. For example, a first column of NVM bit cells may share a first bit line BL-1 and a first source line SL-1. Likewise, a second column of NVM bit cells may share a second bit line BL-2 and a second source line SL-2. Further, a third column of NVM bit cells may share a third bit line BL-3 and a third source line SL-3. As another example, a first row of NVM bit cells may share a first access line AL-1 and a first control line CL-1. Likewise, a second row of NVM bit cells may share a second access line AL-2 and a second control line CL-2. Further, a third row of NVM bit cells may share a third access line AL-3 and a third control line CL-3. In addition, a fourth row of NVM bit cells may share a fourth access line AL-4 and a fourth control line CL-4.

Although FIG. 4 illustrates an array of NVM bit cells with three columns and four rows, the NVM bit-cell array may be formed with any suitable number of NVM bit cells. For example, instances of NVM bit cell 401 may be repeated to form any number of rows and columns to generate an NVM bit-cell array, such as NVM bit-cell array 102, of any size suitable for the application of integrated circuit 100. As described in further detail below with reference to FIG. 5C, certain portions of the active area may be utilized to couple the wells forming the body terminals of the state transistor and the access transistor to the source line SL. For example, active area 402a may be utilized to form a high-doping area suitable to couple the well in which the state transistor and the access transistor reside to the source line SL. As instances of NVM bit cells are repeated up and down to form a column, active area 402a may be repeated at a regular interval within the column to ensure sufficient contact between the well forming the body terminals of the state transistor and access transistor for a given row to the source line SL.

FIG. 5A-5C illustrate cross-section views of an array of non-volatile memory bit cells in accordance with embodiments of the present disclosure.

FIG. 5A illustrates a cross-section view corresponding to cutline 5A in FIG. 4, and specifically along the control line (CL-2) for the second row of NVM bit cells. Accordingly, FIG. 5A illustrates a cross-section of the control gate and the state transistor of NVM bit cell 401 and other NVM bit cells in the same row.

As shown in FIG. 5A, NVM bit cell 401 may be formed on a semiconductor substrate including an epitaxial layer. For example, epitaxial layer 502 may be provided on a semiconductor substrate or may be separately grown on a semiconductor substrate. In some embodiments, the semiconductor substrate may be a p-type semiconductor substrate and epitaxial layer 502 may be a p-type epitaxial layer. Deep well 504 may be formed in epitaxial layer 502. Deep well 504 may have an opposite conductivity type relative to epitaxial layer 502. For example, in embodiments where epitaxial layer 502 is a p-type epitaxial layer, deep well 504 may be an n-type deep well. And in embodiment where epitaxial layer 502 is an n-type epitaxial layer, deep well 504 may be an p-type deep well.

NVM bit cell 401 may include a well region in which the state transistor and the access transistor may be formed. For example, NVM bit cell 401 may include well region 506. As shown in FIG. 5A, well region 506 may be disposed in deep well 504. As also shown in FIG. 5A, deep well 504 may have a deep-well depth that is greater than a well depth of well region 506. Well region 506 may have an opposite conductivity type relative to deep well 504. For example, in embodiments where deep well 504 is an n-type deep well, well region 506 may be a p-well region. In such embodiments, state transistor may be an NMOS transistor and access transistor may be an NMOS transistor. In other embodiments where deep well 504 is a p-type deep well, well region 506 may be an n-well region. In such embodiments, state transistor may be a PMOS transistor and access transistor may be an PMOS transistor.

NVM bit cell 401 may also include one or more trench regions 508. In some embodiments, trench region 508 may have a trench depth that is greater than or equal to a well depth of well region 506. Accordingly, the well region of a first NVM bit cell, such as well region 506 of NVM bit cell 401, may be isolated by trench region 508 from the well region 506n of a neighboring NVM bit cell located in a same row of the NVM bit-cell array. In some embodiments, and depending on the lateral distance between well region 506 and a neighboring well region 506n, the trench depth of trench region 508 may be nominally lesser than the well depth of well region 506 to the extent that the trench depth and the lateral distance between well region 506 and a neighboring well region 506n are sufficient to electrically isolate well region 506 and a neighboring well region 506n.

As shown in FIG. 5A, NVM bit cell 401 may include tunnel oxide layer 520. In some embodiments, tunnel oxide layer 520 may be grown over exposed areas of well region 506. Tunnel oxide layer 520 may thus form the dielectric for the gate of the state transistor of NVM bit cell 401. Thus, for the purposes of the present disclosure, the portions of tunnel oxide layer 520 forming the gate of the state transistor may also be referred to as the state-transistor tunnel oxide layer. Further, first polysilicon layer 530 may be formed over tunnel oxide layer 520. As shown in FIG. 5A, first polysilicon layer 530 may be patterned such the portion of first polysilicon layer 530 within NVM bit cell 401 may be isolated from portions of first polysilicon layer 530 within neighboring NVM bit cells.

Control-gate dielectric layer 540 may be formed over first polysilicon layer 530. As shown in FIG. 5A, control-gate dielectric layer 540 may be formed in a continuous manner spanning NVM bit cell 401, as well as neighboring NVM bit cells, from a spacer 532 at one end of the row to a spacer 532 at the other end of the row. Control-gate dielectric layer 540 may include high-K dielectric layer 541. High-K dielectric layer 541 may be formed with any suitable dielectric material having a dielectric constant greater than the dielectric constant of silicon dioxide. For example, high-K dielectric layer may be formed with one or more layers of any one or more of hafnium oxide, aluminum oxide, and/or tantalum oxide. In some embodiments, control-gate dielectric layer 540 may further include at least one silicon dioxide layer. For example, as shown in FIG. 5A, control-gate dielectric layer 540 may include a first silicon dioxide layer 542a on a first side of the high-K dielectric layer 541 and a second silicon dioxide layer 542b on a second side of high-K dielectric layer 541.

Second polysilicon layer 550 may be formed over control-gate dielectric layer 540. Second polysilicon layer 550 may be formed in a continuous manner spanning NVM bit cell 401, as well as neighboring NVM bit cells, from a spacer 532 at one end of the row to a spacer 532 at the other end of the row. And as shown in FIG. 5A, silicide 552 may be formed on top of second polysilicon layer 550. As described above, silicide 552 may improve the electrical conductivity of contacts (not shown in the cross-section slice of FIG. 5A) between second polysilicon layer 550 and metal layers included above for signal routing.

The various layers described above may be added to the semiconductor substrate to form the state transistor and the control gate of NVM bit cell 401. For example, the state transistor may include a floating-gate terminal formed by first polysilicon layer 530 and coupled to the floating terminal of the control gate. The state transistor may further include tunnel oxide layer 520 formed between the first polysilicon layer 530 and an active area of the state transistor in well region 506.

The control gate may include a floating terminal formed by first polysilicon layer 530. First polysilicon layer 530 may be a shared polysilicon layer that may form both the floating terminal of the control gate and the floating-gate terminal of the state transistor. Accordingly, the floating terminal of the control gate may be coupled to the floating-gate terminal of state transistor by virtue of both terminals be formed by the same shared portion of first polysilicon layer 530. The control gate may further include a control terminal formed by second polysilicon layer 550.

In addition, the control gate may include a control-gate dielectric layer 540 formed between first polysilicon layer 530 and second polysilicon layer 550. As described above, control-gate dielectric layer 540 may include high-K dielectric layer 541. High-K dielectric layer may have a higher dielectric constant than, for example, silicon dioxide. The high-K dielectric layer may thus increase the capacitance across the control gate and improve the capacitive coupling between control terminal formed by second polysilicon layer 550 and the floating terminal formed by first polysilicon layer 530.

The improved capacitive coupling may reduce the voltage necessary to induce Fowler-Nordheim tunneling across the control gate during write and erase operations, such as those operations described above with reference to FIG. 3. The reduced voltage may in turn reduce the stress incurred by the control gate and the state transistor during write and erase operations, thereby improving reliability of NVM bit cell 401. Specifically, the reduced stress incurred by the control gate and the state transistor during write and erase operations may allow NVM bit cell 401 to operate reliably for a large number of write or erase cycles and under harsh environmental conditions. For example, NVM bit cell 401 may be capable of maintaining operation for greater than one million write and/or erase cycles at high temperatures of, for example, 175 degrees Celsius. Moreover, improved reliability may be achieved with a smaller area consumption, and thus a lower manufacturing cost, than for example single poly NVM bit cells.

As shown in FIG. 5A, NVM bit cell 401 may further include oxide 560, as well as first metal layer 561, and second metal layer 562. First metal layer 561 may be patterned according to the first metal layer areas 420 described above with reference to FIG. 4. Similarly, second metal layer 562 may be patterned according to the second metal layer areas 430 also described above with reference to FIG. 4. First metal layer 561 and second metal layer 562 may be utilized to route various signals associated with NVM bit cell 401 and neighboring NVM bit cells. For example, as shown in FIG. 5A, first metal layer 561 may be utilized to route the source line (SL-2) for the second column in which NVM bit cell 401 is located. Further, second metal layer 562 may be utilized to route the bit line (BL-2) for the second column in which NVM bit cell 401 is located. Other patterned portions of first metal layer 561 and second metal layer 562 corresponding to neighboring NVM bit cells may similarly be utilized to route the source lines (SL-1 and SL-3) and the bit lines (BL-1 and BL-3) for neighboring NVM bit cells in the neighboring first and third columns.

FIG. 5B illustrates a cross-section view corresponding to cutline 5B in FIG. 4, and specifically along the access line (AL-2) for the second row of NVM bit cells. Accordingly, FIG. 5B illustrates a cross-section of the access transistor of NVM bit cell 401 and other NVM bit cells in the same row.

As shown in FIG. 5B, the access transistor may be formed in the same well region 506 as the state transistor described above with reference to FIG. 5A. Further, as described above with reference to FIG. 5A, tunnel oxide layer 520 may be grown over exposed areas of well region 506. Tunnel oxide layer 520 may thus form the dielectric for the gate of the access transistor of NVM bit cell 401. Thus, for the purposes of the present disclosure, the portions of tunnel oxide layer 520 forming the gate of the access transistor may also be referred to as the access-transistor tunnel oxide layer.

First polysilicon layer 530 may be formed over tunnel oxide layer 520. First polysilicon layer 530 may thus form the gate terminal of the access transistor of NVM bit cell 401. As shown in FIG. 5B, first polysilicon layer 530 may be formed in a continuous manner spanning NVM bit cell 401, as well as neighboring NVM bit cells, from a spacer 532 at one end of the row to a spacer 532 at the other end of the row. First polysilicon layer 530 may be utilized to route the access line (AL-2) for NVM bit cell 401 as well as the other NVM bit cells located in the same second row as NVM bit cell 401. For example, contact 534 may couple first polysilicon layer 530 to a patterned portion of first metal layer 561 that forms the access line (AL-2).

FIG. 5C illustrates a cross-section view corresponding to cutline 5C in FIG. 4, and specifically along the bit line (BL-2) for the second column of NVM bit cells. Accordingly, FIG. 5C illustrates a cross-section of the control gate and the access gate for NVM bit cell 401 and other NVM bit cells in the same column.

As shown in FIG. 5C, well region 506 may be shared by a first NVM bit cell, such as NVM bit cell 401, and one or more neighboring NVM bit cells located in the same column. Further, different doping may be utilized to form active areas of state transistor and access transistor. For example, a heavy doping of the same conductivity type as well region may be utilized to form heavy-doped region 505. For example, in embodiments where well region 506 is a p-type well region, heavy doped region 505 may likewise be a p-type well region with heavier doping than well region 506. Heavy doped region 505 may thus help provide a low-resistance contact between well region 506, which forms the body terminals of the state transistor and the access transistor of NVM bit cell 401, and the source line (SL-2) for the second column in which NVM bit cell 401 is located.

Additional doping of the opposite conductivity type may also be added to form the source and drain terminals of the state transistor and the access transistor. For example, utilizing one or both of the first polysilicon layer 530 and second polysilicon layer 550 as a mask, a low doping level may be applied to form low-doped regions 507. After subsequent formation of spacers 532, a heavy doping level may be applied to form heavy-doped regions 509. Low-doped regions 507 and heavy-doped regions 509 may be of opposite conductivity type relative to well region 506. For example, embodiments where well region 506 is an p-type well region, low-doped regions and heavy-doped regions 509 may be n-type doping regions. In such embodiments, the state transistor and the access transistor may be NMOS transistors, and n-type low-doped regions 507 and heavy-doped regions 509 may form the source and drain terminals of the NMOS access transistor and the NMOS state transistor. For example, heavy-doped region 509a and low-doped region 507a may collectively form the source terminal of the access transistor of NVM bit cell 401. Further, heavy-doped region 509b and low-doped region 507b may collectively form the drain terminal of the access transistor of NVM bit cell 401. In addition, low-doped region 507c may form both the drain terminal of the state transistor and the source terminal of the access transistor of NVM bit cell 401. In some embodiments, a further heavy-doped region 509 not shown in FIG. 5C may combine with low-doped region 507c to collectively form the drain terminal of the state transistor and the source terminal of the access transistor. For example, spacers 532 may serve as the mask for the heavy doping that forms heavy-doped regions 509. Thus, in embodiments where the gates of the state transistor and the access transistor are further spread apart such that the spacers between the state transistor and the access transistor do not overlap, an additional heavy-doped region 509 centered within low-doped region 507c may be formed.

Silicide 552 may be formed on top of second polysilicon layer 550, as well as on top of heavy-doped regions 509. Silicide 552 may improve the electrical conductivity of contacts 534 to underlying features of NVM bit cell 401, such as the source and drain terminals of the state transistor and access transistor formed in part by heavy-doped regions 509.

As shown in FIG. 5C, contact 534a may couple a portion of first metal layer 561 that forms the source line (SL-2) for the second column to the heavy-doped region 509a that forms in part the source terminal of the state transistor of NVM bit cell 401. Further contact 534b may couple a portion of first metal layer 561 that forms part of the bit line (BL-2) for the second column to the heavy-doped region 509b that forms in part the drain terminal of the access transistor of NVM bit cell 401. As also shown in FIG. 5C, vias 563 may be utilized to couple portions of first metal layer 561 to portions of second metal layer 562. For example, as shown in the cross-sectional slice of FIG. 5C, vias 563a may couple a portion of first metal layer 561 to a portion of second metal layer 562 designated to route the bit line (BL-2) for the second column of the NVM bit cell array.

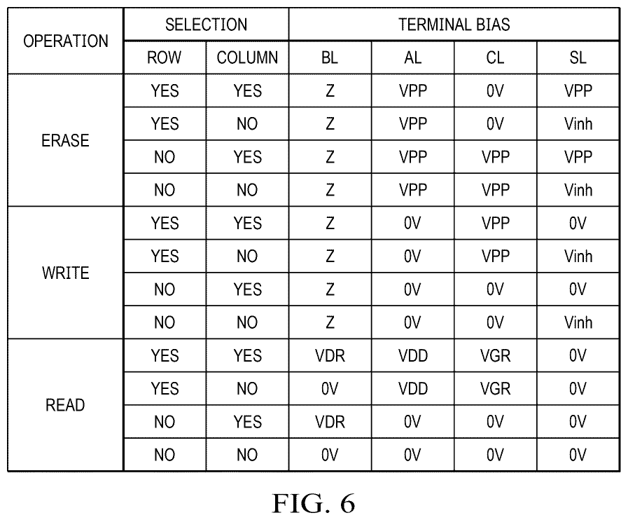

Given the mirrored and repeated arrangement, different instances of NVM bit cells, such as NVM bit cell 401, may share a common well region 506. For example, as described above with reference to FIGS. 5A-5C, the well region 506 of NVM bit cell 401 may be isolated from the well region 506n of neighboring NVM bit cells in the same row but different column by trench region 508. However, the well region 506 of NVM bit cell 401 may be shared with other neighboring NVM bit cells located in different rows of the same column. Moreover, certain lines, such as the access line AL, the control line CL, the source line SL, and the bit line BL may be shared by multiple instances NVM bit cells, such as NVM bit cell 401, located in either the same row or same column. Thus, as described below with reference to FIG. 6, various controls may be applied to an instance of NVM bit cell 401 not only to erase, write, and read that particular instance of NVM bit cell 401, but also to inhibit that instance from changing state when other bit cells in the same row or column may undergo erase or write operations.

FIG. 6 is a chart illustrating operating conditions of an NVM bit cell in accordance with embodiments of the present disclosure. FIG. 6 illustrates, for example, the operation of an NVM bit cell, such as NVM bit cell 401, described above with reference to FIGS. 5A-5C, when included in an array with other instances of NVM bit cells repeated in rows and columns. As described above with reference to FIG. 2, the p-well line PW for the NVM bit cell may be coupled to the source line SL. Thus, the p-well line PW is not separately included in the chart of FIG. 6. Moreover, a single bit line BL, source line SL, control line CL, and access line AL are referenced below, rather than designating such lines for each of different rows and columns.

For an erase operation when both the row and the column for the NVM bit cell are selected, the erase operation may be performed by applying a high impedance to the bit line BL, applying a program voltage VPP to the access line AL and source line SL, and applying a nominal voltage of, for example, 0 volts to the control line CL. The program voltage VPP may be, for example, 10 volts, or any other voltage higher than the voltage applied to the control line CL suitable to induce Fowler-Nordheim tunneling as described above with reference to FIG. 2.

When the row but not the column is selected for the erase operation, a high impedance may be applied to the bit line BL, the program voltage VPP may be applied to the access line AL, and a nominal voltage of for example 0 volts may be applied to the control line CL. Moreover, to prevent unwanted disturbance of the NVM bit cell, a inhibit voltage Vinh may be applied to the source line SL. In some embodiments, the inhibit voltage Vinh applied to the source line SL may be set to a voltage to ensure that the difference between the source line SL and the access line AL does not exceed the voltage capability of the gate dielectric of access transistor 230. The inhibit voltage may also ensure that the difference between the source line SL and the control line CL does not exceed 5 volts for example, thereby ensuring that unwanted tunneling is prevented or reduced. Conversely, when the column but not the row is selected for the erase operation, a high impedance may be applied to the bit line BL, and the program voltage VPP may be applied to each of the access line AL, the control line CL, and the source line SL. Finally, when the column and the row are both not selected for the erase operation, a high impedance may be applied to the bit line BL, the program voltage VPP may be applied to the access line AL and the control line CL, and an inhibit voltage Vinh may be applied to the source line to prevent disturbance to other NVM bit cells in the same column from being disturbed. In some embodiments, the inhibit voltage Vinh applied to the source line SL may be set to a voltage to ensure that the difference between the source line SL and the access line AL does not exceed the voltage capability of the gate dielectric of access transistor 230. The inhibit voltage Vinh may also ensure that the difference between the control line CL and the source line SL does not exceed 5 volts for example, thereby ensuring that unwanted tunneling is prevented or reduced.

For a write operation when both the row and the column for the NVM bit cell are selected, the write operation may be performed by applying a high impedance to the bit line BL, applying the program voltage VPP to the control line, and applying a nominal voltage of for example 0 volts to the access line and the source line. The program voltage VPP may be, for example, 10 volts, or any other voltage higher than the voltage applied to the source line SL suitable to induce Fowler-Nordheim tunneling as described above with reference to FIG. 2.

When the row but not the column is selected for the write operation, a high impedance may be applied to the bit line BL, the program voltage VPP may be applied to the control line CL, and a nominal voltage of for example 0 volts may be applied to the access line AL. Moreover, to prevent unwanted disturbance of the NVM bit cell, a inhibit voltage Vinh may be applied to the source line SL. In some embodiments, the inhibit voltage Vinh applied to the source line SL may be set to a voltage to ensure that the difference between the source line SL and the access line AL does not exceed the voltage capability of the gate dielectric of access transistor 230. The inhibit voltage Vinh may also ensure that the difference between the control line CL and the source line SL does not exceed 5 volts for example, thereby ensuring that unwanted tunneling is prevented or reduced. Conversely, when the column but not the row is selected for the write operation, a high impedance may be applied to the bit line BL, and a nominal voltage of for example 0 volts may be applied to each of the access line AL, the control line CL, and the source line SL. Finally, when the column and the row are both not selected for the write operation, a high impedance may be applied to the bit line BL, a nominal voltage of for example 0 volts may be applied to the access line AL and the control line CL, and an inhibit voltage Vinh may be applied to the source line to prevent disturbance to other NVM bit cells in the same column from being disturbed. In some embodiments, the inhibit voltage Vinh applied to the source line SL may be set to a voltage to ensure that the difference between the source line SL and the access line AL does not exceed the voltage capability of the gate dielectric of access transistor 230. The inhibit voltage Vinh may also ensure that the difference between the source line SL and the control line CL does not exceed 5 volts for example, thereby ensuring that unwanted tunneling is prevented or reduced.

For a read operation, the read operation may be performed by turning on the access transistor, applying a drain-to-source voltage across the state transistor, and monitoring the current conducted by state transistor. For example, when both the row and the column for the NVM bit cell are selected for a read operation, a drive voltage VDR may be applied to the bit line BL, a nominal voltage of for example 0 volts may be applied to the source line, a supply voltage VDD may be applied to the access line, and a gate-read voltage VGR may be applied to the control line. The current conducted by state transistor for the given drain-to-source source voltage may indicate whether the NVM bit cell is in an erase-state or a write-state.

When the row but not the column is selected for the read operation, the supply voltage VDD may be applied to the access line, the gate-read voltage VGR may be applied to the control line, and a nominal voltage of for example 0 volts may be applied to both the bit line BL and the source line SL. Conversely, when the column but not the row is selected for the read operation, the drive voltage VDR may be applied to the bit line BL, but a nominal voltage of for example 0 volts may be applied to each of the access line AL, control line CL, and source line SL. Finally, when neither the row nor the column is selected for the read operation, a nominal voltage of for example 0 volts may be applied to each of the bit line BL, access line AL, control line CL, and source line SL.

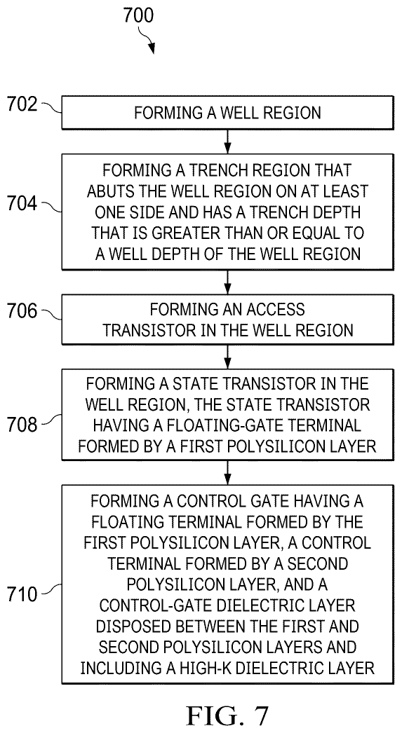

FIG. 7 illustrates method 700 for manufacturing an non-volatile memory (NVM) bit cell in accordance with embodiments of the present disclosure. Method 700 may be performed by any suitable mechanism. Method 700 may be performed with fewer or more steps than shown in FIG. 7. Moreover, steps of method 700 may be omitted, repeated, performed in parallel, performed in a different order than shown in FIG. 7, or performed recursively. One or more steps of method 700, although shown in an order, may be performed at the same time or in a re-ordered manner. As one example of steps being performed in a different order than shown in FIG. 7, step 704 may be performed before step 702. And as one example of steps being performed in parallel, step 706 and step 708 may be performed at least in part in parallel to each other during the same semiconductor process steps.

Step 702 may include forming a well region. For example, as shown in FIGS. 5A-5C, well region 506 may be formed in deep well 504.

Step 704 may include forming a trench region that abuts the well region on at least one side and has a trench depth that is greater than or equal to the well depth. For example, as shown in FIGS. 5A and 5B, trench region 508 may be formed in deep well 504 and may abut well region 506 on at least one side. Further, trench region 508 may be formed with a trench depth that is greater than or equal to the well depth of well region 506.

Step 706 may include forming an access transistor in the well region. For example, as described above with reference to FIG. 5B, the access transistor of NVM bit cell 401 may be formed in the same well region 506 as the state transistor of NVM bit cell 401.

Step 708 may include forming a state transistor in the well region, the state transistor having a floating-gate terminal formed by a first polysilicon layer. For example, as shown in FIG. 5A, the state transistor of NVM bit cell 401 may be formed in well region 506. Moreover, the state transistor may have a floating-gate terminal formed by first polysilicon layer 530.

Step 710 may include forming a control gate having a floating terminal formed by the first polysilicon layer, a control terminal formed by a second polysilicon layer, and a control gate dielectric disposed between the first and second polysilicon layers and including a high-K dielectric layer. For example, as described above with reference to FIG. 5A, a floating terminal of the control gate may be formed by first polysilicon layer 530. Further, a control terminal of the control gate may be formed by second polysilicon layer 550. The control gate may include control-gate dielectric layer 540 disposed between first polysilicon layer 530 and second polysilicon layer 550. The control-gate dielectric layer 540 may include high-K dielectric layer 541. In some embodiments, control-gate dielectric layer 540 may be formed with a first silicon dioxide layer 542a on a first side of the high-K dielectric layer 541 and a second silicon dioxide layer 542b on a second side of the high-K dielectric layer 541.

Although examples have been described above, other modifications and variations may be made from this disclosure without departing from the spirit and scope of these examples. The above descriptions of various embodiments illustrate the principles of the invention. Numerous variations and modifications will become apparent to those skilled in the art based on the above disclosure. The following claims are intended to embrace all such variations and modifications.

What is claimed is:

1. A non-volatile memory (NVM) bit cell, comprising:
a control gate comprising:
floating terminal formed by a first polysilicon layer;
a control terminal formed by a second polysilicon layer; and
a control-gate dielectric layer formed between the first polysilicon layer and the second polysilicon layer, wherein the control-gate dielectric layer includes a high-K dielectric layer;
a state transistor comprising:
a floating-gate terminal formed by the first polysilicon layer and coupled to the floating terminal of the control gate; and
a tunnel oxide layer formed between the first polysilicon layer and an active area of the state transistor; and
an access transistor coupled in series with the state transistor.

2. The NVM bit cell of claim 1, further comprising:
a well region in which the state transistor and the access transistor are formed; and
a trench region having a trench depth that is greater than or equal to a well depth of the well region.

3. The NVM bit cell of claim 2, wherein:
the well region is a p-well region; and
the state transistor and the access transistor are NMOS transistors.

4. The NVM bit cell of claim 2, wherein:
the well region is disposed in a deep well; and
the well region has an opposite conductivity type relative to the deep well.

5. The NVM bit cell of claim 1, wherein the state transistor and the control gate are collectively configured to utilize Fowler-Nordheim tunneling for an erase operation and a write operation.

6. The NVM bit cell of claim 1, wherein the control-gate dielectric layer further includes at least one silicon dioxide layer.

7. The NVM bit cell of claim 1, wherein the control-gate dielectric layer further includes a first silicon dioxide layer on a first side of the high-K dielectric layer and a second silicon dioxide layer on a second side of the high-K dielectric layer.

8. An integrated circuit, comprising:
a logic block; and
a non-volatile memory (NVM) bit-cell array coupled to the logic block, the NVM bit-cell array comprising a plurality of NVM bit cells arranged in multiple rows and in multiple columns, each NVM bit cell comprising:
a control gate comprising:
floating terminal formed by a first polysilicon layer;
a control terminal formed by a second polysilicon layer; and
a control-gate dielectric layer formed between the first polysilicon layer and the second polysilicon layer, wherein the control-gate dielectric layer includes a high-K dielectric layer;
a state transistor comprising:
a floating-gate terminal formed by the first polysilicon layer and coupled to the floating terminal of the control gate; and
a tunnel oxide layer formed between the first polysilicon layer and an active area of the state transistor; and
an access transistor coupled in series with the state transistor.

9. The integrated circuit of claim 8, wherein each NVM bit cell further comprises:
a well region in which the state transistor and the access transistor are formed; and
a trench region having a trench depth that is greater than or equal to a well depth of the well region.

10. The integrated circuit of claim 9, wherein:
the well region is a p-well region; and
the state transistor and the access transistor are NMOS transistors.

11. The integrated circuit of claim 9, wherein:
the well region is disposed in a deep well; and
the well region has an opposite conductivity type relative to the deep well.

12. The integrated circuit of claim 9, wherein the well region is shared by a first NVM bit cell and one or more neighboring NVM bit cells located in a same column.

13. The integrated circuit of claim 9, wherein the well region of a first NVM bit cell is isolated by the trench region from the well region of a neighboring NVM bit cell located in a same row.

14. The integrated circuit of claim 8, wherein the state transistor and the control gate are collectively configured to utilize Fowler-Nordheim tunneling for an erase operation and a write operation.

15. The integrated circuit of claim 8, wherein the control-gate dielectric layer further includes at least one silicon dioxide layer.

16. The integrated circuit of claim 8, wherein the control-gate dielectric layer further includes a first silicon dioxide layer on a first side of the high-K dielectric layer and a second silicon dioxide layer on a second side of the high-K dielectric layer.

17. A method, comprising:
forming a well region;
forming an access transistor in the well region;
forming a state transistor in the well region, the state transistor having a floating-gate terminal formed by a first polysilicon layer;
forming a control gate having a floating terminal formed by the first polysilicon layer, a control terminal formed by a second polysilicon layer, and a control-gate dielectric layer disposed between the first and second polysilicon layers and including a high-K dielectric layer.

18. The method of claim 17, further comprising forming a trench region that abuts the well region on at least one side and has a trench depth that is greater than or equal to a well depth of the well region.

19. The method of claim 17, wherein the control-gate dielectric layer is formed with a first silicon dioxide layer on a first side of the high-K dielectric layer and a second silicon dioxide layer on a second side of the high-K dielectric layer.

20. The method of claim 17, wherein the state transistor and the control gate are collectively configured to utilize Fowler-Nordheim tunneling for an erase operation and a write operation.
